(19) United States
(12) Patent Application Publication
(10) Pub. No.: US 2026/0180535 A1
(43) Pub. Date: Jun. 25, 2026

(54) AUTOMATIC GAIN CONTROLLER

(71) Applicant: ELITE SEMICONDUCTOR MICROELECTRONICS TECHNOLOGY INC., Hsinchu City (TW)

(72) Inventors: ZIH-SIANG SYONG, Hsinchu City (TW); ISAAC Y. CHEN, Hsinchu City (TW)

(73) Assignee: ELITE SEMICONDUCTOR MICROELECTRONICS TECHNOLOGY INC., Hsinchu City (TW)

(21) Appl. No.: 18/988,973

(22) Filed: Dec. 20, 2024

(51) Int. Cl. H03G 3/30

(52) U.S. Cl. CPC H03G 3/3026

(57) ABSTRACT

An automatic gain controller includes multiple resistors, multiple switches, a buffer, a charge pump circuit and a voltage level shifter. The resistors are connected in series between an input terminal for receiving an input signal and an inverting input terminal of an operational amplifier. Each of the switches has a first terminal coupled to a corresponding one of the resistors, and a second terminal coupled to the inverting input terminal. The switches are respectively controlled by multiple switching signals so as to be turned on or turned off. The buffer generates a buffer signal according to the voltage at the inverting input terminal. The charge pump circuit generates a boost voltage according to the buffer signal and a clock signal. The voltage level shifter converts voltage levels of multiple control signals according to the buffer signal and the boost voltage to generate and respectively output the switching signals to the switches.

### BACKGROUND OF THE INVENTION

### 1. Field of the Invention

The present disclosure relates to a controller, and in particular to an automatic gain controller.

### 2. Description of the Related Art

Referring to FIG. 1, a current class D amplifier (an audio amplifier) 1 includes an integration circuit 11, a signal generation circuit 12 and other required elements. The integration circuit 11 is for receiving an input signal Vin (for example, an audio signal), and generating an integration signal Is according to the input signal Vin. The signal generation circuit 12 is for receiving the integration signal Is, and performing pulse width modulation (PWM) and amplification according the integration signal Is to generate and output an amplified signal Am to a speaker, so that the speaker 10 plays the audio signal according to the amplified signal Am.

However, each of switches sw1 to sw4 included in an automatic gain controller 111 in the integration circuit 11 for controlling the class D amplifier 1 is a transmission gate. Taking the four switches sw1 to sw4 herein for example, the switches sw1 to sw4 are respectively controlled by four control signals C1 to C4 so as to be turned on or turned off. The transmission gate is a switch formed by a combination of a P-type metal oxide semiconductor field effect transistor (MOSFET) and an N-type MOSFET. An on resistance of each transmission gate varies along with a change in the input signal Vin, such that a total input resistance value (for example, the total input resistance value is r1+r2+r3+Ron when the switch sw4 is turned on while the remaining switches s1 to s3 are turned off, wherein r1 to 3 are respective resistance values of resistors R1 to R3 and Ron is an on resistance (a non-constant value) of the switch Sw4) also varies, and the class D amplifier 1 does not have a constant gain. Moreover, a total harmonic distortion (THD) is larger, further affecting the playback quality of the speaker 10. Although current techniques are available for improving the issue of a large THD by means of increasing the size of each transmission gate, such method inevitably leads a greater circuit area of the class D amplifier.

### BRIEF SUMMARY OF THE INVENTION

Therefore, it is an object of the present disclosure to provide an automatic gain controller having a constant on resistance for an audio amplifier to have a constant gain as well as having smaller total harmonic distortion and circuit area, for use in an integration circuit of the audio amplifier, so as to improve the drawbacks of the prior art.

An automatic gain controller of the present disclosure is suitable for an integration circuit of an audio amplifier, wherein the integration circuit includes an operational amplifier. The automatic gain controller includes: multiple resistors, connected in series between an input terminal and an inverting input terminal of the operational amplifier, the input terminal for receiving an input signal; multiple switches, each of which having a first terminal coupled to a corresponding one of the resistors and a second terminal coupled to the inverting terminal of the operational amplifier, the switches respectively controlled by multiple switching signals so as to be turned on or turned off; a buffer, coupled between the inverting terminal of the operational amplifier, and generating a buffer signal according to a voltage at the inverting terminal, the voltage at the inverting terminal being associated with the input signal; a charge pump circuit, coupled to the buffer to receive the buffer signal, and generating a boost voltage according to the buffer signal and a clock signal; and a voltage level shifter, coupled to the switches and coupled to the buffer and the charge pump circuit to respectively receive the buffer signal and the boost voltage, and converting voltage levels of the multiple control signals according to the buffer signal and the boost signal to generate and respectively output the switching signals to the switches.

In some embodiments, each of the switches of the automatic gain controller of the present disclosure is an N-type metal oxide semiconductor field effect transistor (MOSFET).

In some embodiments, the charge pump circuit of the automatic gain controller includes: an inverting unit, for receiving the clock signal, and generating a first inverted signal and a second inverted signal according to the clock signal; a first transistor, having a first terminal coupled to the buffer to receive the buffer signal, a second terminal, and a control terminal; a second transistor, having a first terminal, a second terminal, and a control terminal respectively coupled to the first terminal, the control terminal and the second terminal of the first transistor; a first capacitor, having a first terminal coupled to the second terminal of the first transistor, and a second terminal coupled to the inverting unit to receive the first inverted signal; a second capacitor, having a first terminal coupled to the second terminal of the second transistor, and a second terminal coupled to the inverting unit to receive the second inverted signal; a third transistor and a fourth transistor, each of which having a first terminal coupled to the first terminal of the second capacitor, a second terminal, and a control terminal coupled to the first terminal of the first capacitor; a fifth transistor and a sixth transistor, each of which having a first terminal coupled to the first terminal of the first capacitor, a second terminal, and a control terminal coupled to the first terminal of the second capacitor, the second terminal of the fifth transistor coupled to the second terminal of the third transistor, the second terminal of the sixth transistor coupled to the second terminal of the fourth transistor; and a seventh transistor, having a first terminal and a second terminal coupled to the buffer to receive the buffer signal, and a control terminal coupled to the second terminal of the fourth transistor and providing the boost voltage.

In some embodiments, the inverting unit of the automatic gain controller of the present disclosure includes a first inverter, a second inverter and a third inverter that are sequentially connected in series. An input terminal of the first inverter is for receiving the clock signal, an output terminal of the second inverter is coupled to the second terminal of the first capacitor and outputs the first inverted signal, and an output terminal of the third inverter is coupled to the second terminal of the second capacitor and outputs the second inverted signal.

In some embodiments, in the charge pump circuit of the automatic gain controller of the present disclosure, each of the first transistor, the second transistor and the seventh transistor is a low dropout N-type MOSFET, and each of the third transistor to the sixth transistor is a low dropout P-type MOSFET.

In some embodiments, the voltage level shifter of the automatic gain controller of the present disclosure includes multiple voltage level shifting circuits. Each of the voltage level shifting circuits is coupled to a corresponding one of the switches and coupled to the buffer and the charge pump circuit to respectively receive the buffer signal and the boost voltage, and converts a voltage level of a corresponding one of the control signals according to the buffer signal and the boost voltage to generate and output a corresponding one of the switching signals to the corresponding one of the switches.

In some embodiments, each of the voltage level shifting circuits of the automatic gain controller of the present disclosure includes: an inverter, having an input terminal for receiving the corresponding one of the control signals, and an output terminal outputting an inverted signal; a first transistor, having a first terminal coupled to the charge pump circuit to receive the boost voltage, a second terminal, and a control terminal; a second transistor, having a first terminal, a second terminal, and a control terminal respectively coupled to the first terminal, the control terminal and the second terminal of the first transistor; a third transistor, having a first terminal coupled to the second terminal of the first transistor, a second terminal, and a control terminal coupled to the buffer to receive the buffer signal; a fourth transistor, having a first terminal coupled to the second terminal of the second transistor, a second terminal providing the corresponding one of the switching signals, and a control terminal coupled to the buffer to receive the buffer signal; a fifth transistor, having a first terminal coupled to the second terminal of the third transistor, a second terminal, and a control terminal for receiving a supply voltage; a sixth transistor, having a first terminal coupled to the second terminal of the fourth transistor, a second terminal, and a control terminal for receiving the supply voltage; a seventh transistor, having a first terminal coupled to the second terminal of the fifth transistor, a second terminal, and a control terminal coupled to the output terminal of the inverter to receive the inverted signal; and an eighth transistor, having a first terminal coupled to the second terminal of the sixth transistor, a second terminal coupled to the second terminal of the seventh transistor, and a control terminal coupled to the input terminal of the inverting terminal.

In some embodiments, in each of the voltage level shifting circuits of the automatic gain controller of the present disclosure, each of the first transistor to the fourth transistor is a P-type MOSFET, and each of the fifth transistor to the eighth transistor is an N-type MOSFET.

In some embodiments, in each of the voltage level shifting circuits of the automatic gain controller of the present disclosure, each of the first transistor to the eighth transistor is a low dropout transistor.

In some embodiments, the audio amplifier for which the automatic gain controller of the present disclosure is suitable is a class D amplifier.

The present disclosure provides the following effects. By using the switching signals generated by coordination of the charge pump circuit and voltage level shifter, the switches have constant on resistances when turned on, further enabling the audio amplifier to have a constant gain and a smaller total harmonic distortion. Thus, the present disclosure is capable of improving the issue of a large total harmonic distortion without increasing the size of each transmission gate as in the prior art. Moreover, the transistors used in the present disclosure are implemented by low dropout transistors, hence providing the audio amplifier with a smaller circuit area.

### BRIEF DESCRIPTION OF THE DRAWINGS

Other features and effects of the present disclosure will become more readily apparent in the embodiments described with reference to the accompanying drawings, wherein

FIG. 1 is a circuit block diagram of an implementation example of a current class D amplifier.

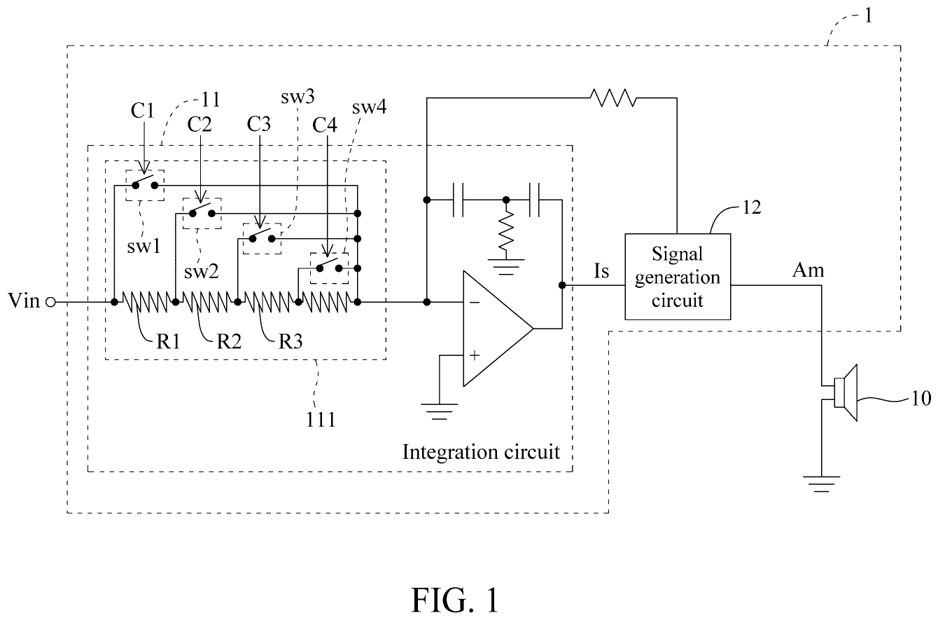

FIG. 2 is a circuit block diagram of an automatic gain controller for an audio amplifier according to an embodiment of the present disclosure.

FIG. 3 is a schematic diagram of waveforms of a switching signal, a buffer signal and a boost signal of the embodiment.

FIG. 4 is a circuit block diagram of a charge pump circuit of the embodiment.

FIG. 5 is a circuit block diagram of a voltage level shifting circuit in a voltage level shifter of the embodiment.

### DETAILED DESCRIPTION OF THE INVENTION

In the following disclosure of the present disclosure, details of the present disclosure are given by way of the embodiments with reference to the accompanying drawings, so as to help a person skilled in the art to better understand the objects, characteristics and effects of the present disclosure. It should be noted that, in the description below and the appended claims, the terms “include” and “comprise” are used in the sense of an open manner, and are not to be construed as closed terms such as “consisting of . . . ”. Moreover, the term “couple” is intended to represent indirect or direct coupling. Thus, if one apparatus is coupled to another apparatus, the connection in between can be implemented by direct coupling or be implemented by indirect coupling achieved with another apparatus in between. Moreover, in the detailed description and claims below, terms such as “first”, “second” and “third” are used to distinguish differences among elements, and are not to be construed as limiting the elements themselves or representing specific orders of the elements. Before the detailed description of the present disclosure is provided, it should be noted that similar elements in different embodiments are denoted by the same symbols or numerals in the disclosure below.

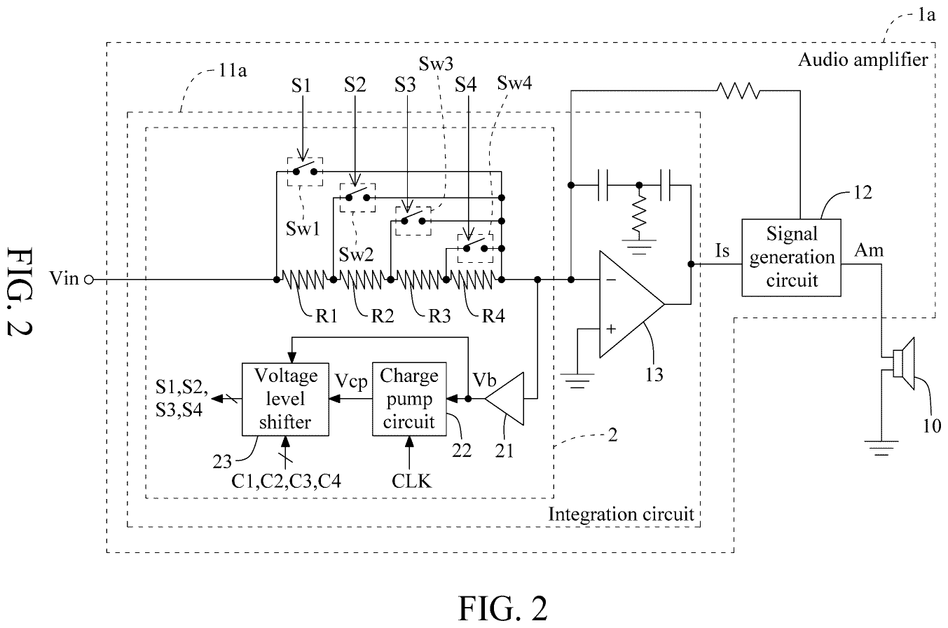

Referring to FIG. 2, an integration circuit 11a of an automatic gain controller 2 suitable for an audio amplifier 1a according to an embodiment of the present disclosure is described below. The audio amplifier 1a is, for example, a class D amplifier, and includes the integration circuit 11a, a signal generation circuit 12 and other required elements. The integration circuit 11a is an integrator including an operational amplifier 13 and other required elements. The integration circuit 11a is for receiving an input signal Vin (for example, an audio signal), and generating an integration signal Is at an output terminal to the operation amplifier 13 according to the input signal Vin. The integration signal Is is an integration of the input signal Vin for time. The signal generation circuit 12 is coupled to an output terminal of the operational amplifier 13 to receive the integration signal Is, and performs pulse width modulation (PWM) and amplification according the integration signal Is to generate and output an amplified signal Am to a speaker 10, so that the speaker 10 plays the audio signal according to the amplified signal Am. It should be noted that, the configuration and operation of the signal generation circuit 12 are generally known to a person of ordinary skill in the art, and associated details are omitted herein for brevity.

In this embodiment, the automatic gain controller 12 is for receiving the input signal Vi and is coupled to an inverting input terminal of the operational amplifier 13. The automatic gain controller 2 generates and outputs an output signal according to the input signal Vin to the inverting input terminal of the operational amplifier 13 for integration, and outputs the integration signal Is at the output terminal of the operational amplifier 13. The automatic gain controller 2 includes multiple resistors R1, R2, R3 and R4, multiple switches Sw1, Sw2, Sw3 and Sw4, a buffer 21, a charge pump circuit 22, and a voltage level shifter 23.

The resistors R1 to R4 are connected in series between the input terminal for receiving the input signal Vin and the inverting input terminal of the operational amplifier 13. Each of the switches Sw1 to Sw4 has a first terminal coupled to a corresponding one of the resistors R1 to R4, and a second terminal coupled to the inverting input terminal of the operational amplifier 13. For example, the first terminal and the second terminal of the switch Sw1 are respectively coupled to the first terminal of the resistor R1 and the inverting input terminal of the operational amplifier 13. The switches sw1 to sw4 are respectively controlled by multiple control signals S1 to S4 so as to be turned on or turned off. In this embodiment, each of the switches Sw1 to Sw4 is an N-type MOSFET, and the gate of the N-type MOSFET receives a corresponding one of the switching signals S1 to S4. The drain and the source of the N-type MOSFET are respectively the first terminal and the second terminal of a corresponding one of the switches Sw1 to Sw4. The number of the resistors is equal to the number of the switches, and each of the numbers is, for example but not limited to, four.

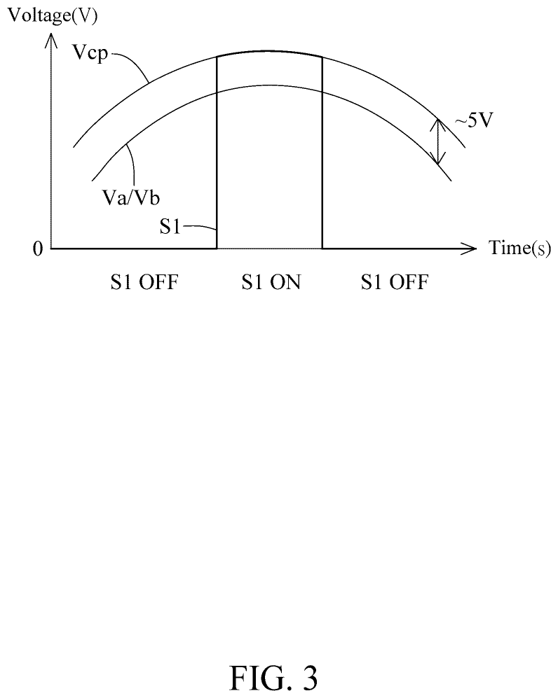

The buffer 21 is coupled to the inverting input terminal of the operational amplifier 13, and generates a buffer signal Vb (for example, 0 to 5 V) according to a voltage (i.e., the voltage of the output signal described above) at the inverting input terminal, wherein the voltage at the inverting input terminal is associated with the input signal Vin. The charge pump circuit 22 is coupled to the buffer 21 to receive the buffer signal Vb, and generates a boost voltage Vcp (for example, Vcp=Vb+5 v, to 10 V, as FIG. 3 showing a schematic diagram of waveforms of the switching signal S1, the buffer signal Vb and the boost signal Vcp, wherein the denotation Va is a signal received by the buffer 21, that is, a signal of the buffer signal Vb before passing through the buffer 21) according to the buffer signal Vb and a clock signal CLK. The clock of the clock signal CLK is the same as the clock of the amplification signal Am. The voltage level shifter 23 is coupled to the switches Sw1 to Sw4, and coupled to the buffer 21 and the charge pump circuit 22 to respectively receive the buffer signal Vb and the boost voltage Vcp, and converts voltage levels of the control signals C1 to C4 (for example, 0 to 5 V) according to the buffer signal Vb and the boost voltage Vcp to generate and respectively output the switching signals S1 to S4 (for example, 0 to 10 V) to the switches Sw1 to Sw4. As such, with the switching signals S1 to S4 generated by coordination of the charge pump circuit 22 and the voltage level shifter 23, a gate voltage Vgs of each of the switches Sw1 to Sw4 can be a constant voltage (for example, 5 V) when the corresponding one of the switches Sw1 to Sw4 is turned on, instead of varying along with the change in the input signal Vin. Thus, the switches Sw1 to Sw4 can have constant on resistances, so that the audio amplifier 1a has a constant gain, and the total harmonic distortion (THD) is also smaller.

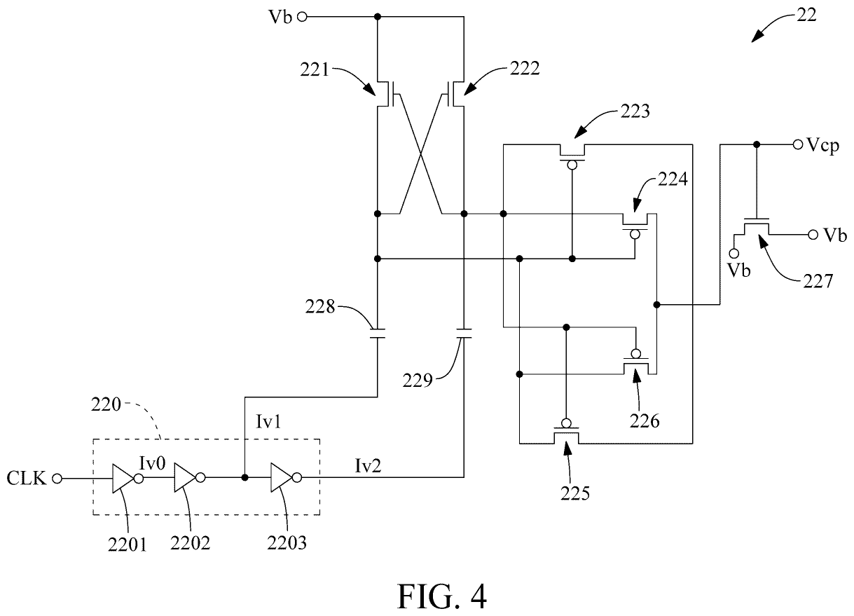

Further referring to FIG. 4, in this embodiment, the charge pump circuit 22 includes an inverting unit 220, a first transistor 221 to a seventh transistor 227, a first capacitor 228 and a second capacitor 229.

The inverting unit 220 is for receiving the clock signal CLK, and generating a first inverted signal Iv1 and a second inverted signal Iv2 according to the clock signal CLK. In this embodiment, the inverting unit 220 includes a first inverter 2201, a second inverter 2202 and a third inverter 2203 sequentially connected in series. An input terminal of the first inverter 2201 is for receiving the clock signal CLK, and accordingly generating an inverted signal Iv0. An input terminal of the second inverter 2202 is for receiving the inverted signal Iv0, and generating and outputting the first inverted signal Iv1 at an output terminal thereof according to the inverted signal Iv0. An input terminal of the third inverter 2203 is for receiving the first inverted signal Iv1, and generating and outputting the second inverted signal Iv2 at an output terminal thereof according to the first inverted signal Iv1.

The first transistor 221 has a first terminal coupled to the buffer 21 to receive the buffer signal Vb, a second terminal, and a control terminal. The second transistor 222 has a first terminal, a second terminal and a control terminal respectively coupled to the first terminal, the control terminal and the second terminal of the first transistor 221. The first capacitor 228 has a first terminal coupled to the second terminal of the first transistor 221, and a second terminal coupled to the output terminal of the second inverter 2202 to receive the first inverted signal Iv1. The second capacitor 229 has a first terminal coupled to the second terminal of the second transistor 222, and a second terminal coupled to the output terminal of the third inverter 2203 to receive the second inverted signal Iv2. Each of the third transistor 223 and the fourth transistor 224 has a first terminal coupled to the first terminal of the second capacitor 229, a second terminal, and a control terminal coupled to the first terminal of the first capacitor 228. Each of the fifth transistor 225 and the sixth transistor 226 has a first terminal coupled to the first terminal of the first capacitor 228, a second terminal, and a control terminal coupled to the first terminal of the second capacitor 229. The second terminal of the fifth transistor 225 is coupled to the second terminal of the third transistor 223. The second terminal of the sixth transistor 226 is coupled to the second terminal of the fourth transistor 224. The seventh transistor 227 has a first terminal and a second terminal coupled to the buffer 21 to receive the buffer signal Vb, and a control terminal coupled to the second terminal of the fourth transistor 224 and providing the boost voltage Vcp. In this embodiment, each of the first transistor 221, the second transistor 222 and the seventh transistor 227 is an N-type MOSFET, the seventh transistor 227 is used as a metal oxide semiconductor (MOS) capacitor, and each of the third transistor 223 to the sixth transistor 226 is a P-type MOSFET; however, the present disclosure is not limited to the examples above.

In this embodiment, the voltage level shifter 23 includes multiple independent voltage level shifting circuits (not shown) that are not connected to one another. The number of the voltage level shifting circuits is equal to the number of the switches Sw1 to Sw4; that is, the voltage level shifter 23 includes four voltage level shifting circuits. Each of the voltage level shifting circuits is coupled to a corresponding one of the switches Sw1 to Sw4, and coupled to the buffer 21 and the charge pump circuit 22 to respectively receive the buffer signal Vb and the boost voltage Vcp, and converts a voltage level of a corresponding one of the control signals C₁ to C₄ according to the buffer signal Vb and the boost voltage Vcp to generate and output the corresponding one of the switching signals S1 to S4 (for example, 0 to 10 V) to the corresponding one of the switches Sw1 to Sw4. For example, the first voltage level shifting circuit is coupled to the switch Sw1, and coupled to the buffer 21 and the charge pump circuit 22 to respectively receive the buffer signal Vb and the boost voltage Vcp, and converts the voltage level of the control signal C1 according to the buffer signal Vb and the boost voltage Vcp to generate and output the switching signal S1 to the switch Sw1. The second voltage level shifting circuit is coupled to the switch Sw2, and coupled to the buffer 21 and the charge pump circuit 22 to respectively receive the buffer signal Vb and the boost voltage Vcp, and converts the voltage level of the control signal C2 according to the buffer signal Vb and the boost voltage Vcp to generate and output the switching signal S2 to the switch Sw2. The connection relations and operations of the voltage level shifting circuits can be deduced accordingly.

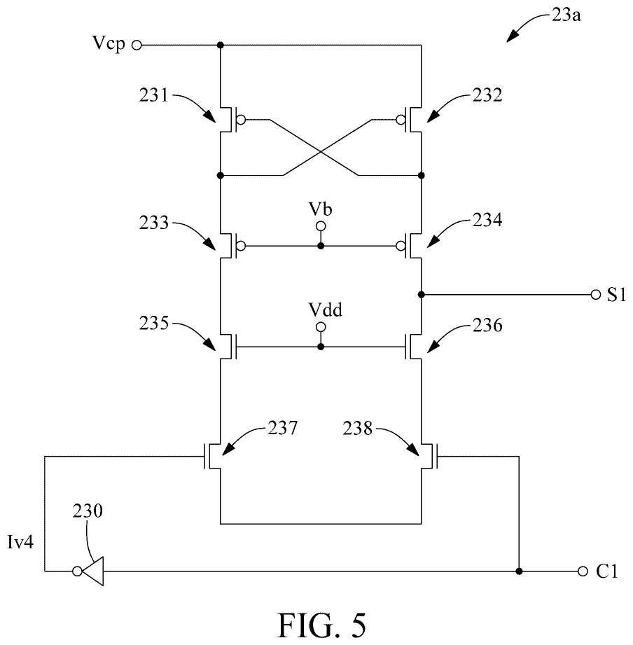

Further referring to FIG. 5, each of the voltage level shifting circuits, as shown by the voltage level shifting circuit 23a in FIG. 5, includes an inverter and a first transistor 231 to an eighth transistor 238. In FIG. 5, for example, the voltage level shifting circuit 23a serving as the first voltage level shifting circuits to generate the switching signal S1 to control the switch Sw1 is described for related connection and operation. The related connections and operations of the remaining three voltage level shifting circuits are similar, and associated details are omitted herein.

The inverter 230 has an input terminal for receiving the corresponding one (that is, the control signal C1) of the control signals C1 to C4, and an output terminal outputting an inverted signal Iv4. The first transistor 231 has a first terminal coupled to the charge pump circuit 22 to receive the boost voltage Vcp, a second terminal, and a control terminal. The second transistor 232 has a first terminal, a second terminal and a control terminal respectively coupled to the first terminal, the control terminal and the second terminal of the first transistor 231. The third transistor 233 has a first terminal coupled to the second terminal of the first transistor 231, a second terminal, and a control terminal coupled to the buffer 21 to receive the buffer signal Vb. The fourth transistor 234 has a first terminal coupled to the second terminal of the second transistor 232, a second terminal providing the corresponding one (that is, the switching signal S1) of the switching signals S1 to S4, and a control terminal coupled to the buffer 21 to receive the buffer signal Vb. The fifth transistor 235 has a first terminal coupled to the second terminal of the third transistor 233, a second terminal, and a control terminal for receiving a supply voltage Vdd (for example, 5 V). The sixth transistor 236 has a first terminal coupled to the second terminal of the fourth transistor 234, a second terminal, and a control terminal for receiving the supply voltage Vdd. The seventh capacitor 237 has a first terminal coupled to the second terminal of the fifth transistor 235, a second terminal, and a control terminal coupled to the output terminal of the inverter 230 to receive the inverted signal Iv4. The eighth transistor 238 has a first terminal coupled to the second terminal of the sixth transistor 236, a second terminal coupled to the second terminal of the seventh transistor 237, and a control terminal coupled to the input terminal of the inverter 230. In this embodiment, each of the first transistor 231 to the fourth transistor 234 is a P-type MOSFET, and each of the fifth transistor 235 to the eighth transistor 238 is an N-type MOSFET; however, the present disclosure is not limited to the examples above.

In conclusion, by using the switching signals S1 to S4 generated by the coordination of the charge pump circuit 22 and voltage level shifter 23, the gate voltage Vgs of each of the switches Sw1 to Sw4 stays as a constant voltage when the corresponding one of the switches Sw1 to Sw4 is turned on, and does not vary along with the change in the input signal Vin, such that the switches Sw1 to Sw4 have constant on resistances and the total input resistance value is also constant. For example, while the switch Sw4 is turned on and the remaining switches Sw1 to Sw3 are turned off, the total resistance value at this point is a constant value (that is, r1+r2+r3+Ron), wherein r1 to r3 are resistance values (constant values) of the resistors R1 to R3 and Ron is the on resistance (a constant value) of the switch Sw4. Thus, the audio amplifier 1a is has a constant gain and the total harmonic distortion is less, hence providing with the speaker 10 with better playback quality. As such, the present disclosure is capable of improving the issue of a large total harmonic distortion without increasing the size of each transmission gate as in the prior art. Moreover, the transistors used in the present disclosure are implemented by low dropout (5 V) transistors, hence providing the audio amplifier 1a with a smaller circuit area.

The description above provides merely preferred embodiments of the present application, and is not to be construed as limitations to the scope of implementation of the present invention. All simple and equivalent variations and modifications made based on the scope of claims and the description of the present application are to be encompassed within the scope of the present application.

What is claimed is:

1. An automatic gain controller, suitable for an integration circuit of an audio amplifier, the integration circuit comprising an operational amplifier, the automatic gain controller comprising:
a plurality of resistors, connected in series between an input terminal and an inverting input terminal of the operational amplifier, the input terminal for receiving an input signal;
a plurality of switches, each of which having a first terminal coupled to a corresponding one of the plurality of resistors, and a second terminal coupled to the inverting input terminal of the operational amplifier, the plurality of switches respectively controlled by a plurality of switching signals so as to be turned on or turned off;
a buffer, coupled to the inverting input terminal of the operational amplifier, and generating a buffer signal according to a voltage at the inverting input terminal, the voltage at the inverting input terminal being associated with the input signal;
a charge pump circuit, coupled to the buffer to receive the buffer signal, and generating a boost voltage according to the buffer signal and a clock signal; and
a voltage level shifter, coupled to the plurality of switches and coupled to the buffer and the charge pump circuit to respectively receive the buffer signal and the boost voltage, and converting voltage levels of the control signals according to the buffer signal and the boost voltage to generate and respectively output the switching signals to the plurality of switches.

2. The automatic gain controller according to claim 1, wherein each of the plurality of switches is an N-type metal oxide semiconductor field effect transistor (MOSFET).

3. The automatic gain controller according to claim 1, wherein the charge pump circuit comprises:
an inverting unit, for receiving the clock signal, and generating a first inverted signal and a second inverted signal according to the clock signal;
a first transistor, having a first terminal coupled to the buffer to receive the buffer signal, a second terminal, and a control terminal;
a second transistor, having a first terminal, a second terminal and a control terminal respectively coupled to the first terminal, the control terminal and the second terminal of the first transistor;
a first capacitor, having a first terminal coupled to the second terminal of the first transistor, and a second terminal coupled to the inverting unit to receive the first inverted signal;
a second capacitor, having a first terminal coupled to the second terminal of the second transistor, and a second terminal coupled to the inverting unit to receive the second inverted signal;
a third transistor and a fourth transistor, each of which having a first terminal coupled to the first terminal of the second capacitor, a second terminal, and a control terminal coupled to the first terminal of the first capacitor;
a fifth transistor and a sixth transistor, each of which having a first terminal coupled to the first terminal of the first capacitor, a second terminal, and a control terminal coupled to the first terminal of the second capacitor, the second terminal of the fifth transistor coupled to the second terminal of the third transistor, the second terminal of the sixth transistor coupled to the second terminal of the fourth transistor; and
a seventh transistor, having a first terminal and a second terminal coupled to the buffer to receive the buffer signal, and a control terminal coupled to the second terminal of the fourth transistor and providing the boost voltage.

4. The automatic gain controller according to claim 3, wherein the inverting unit comprises a first inverter, a second inverter and a third inverter that are sequentially connected in series, an input terminal of the first inverter is for receiving the clock signal, an output terminal of the second inverter is coupled to the second terminal of the first capacitor and outputs the first inverted signal, and an output terminal of the third inverter is coupled to the second terminal of the second capacitor and outputs the second inverted signal.

5. The automatic gain controller according to claim 3, wherein each of the first transistor, the second transistor and the seventh transistor is a low dropout N-type MOSFET, and each of the third transistor to the sixth transistor is a low dropout P-type MOSFET.

6. The automatic gain controller according to claim 1, wherein the voltage level shifter comprises a plurality of voltage level shifting circuits, each of which is coupled to a corresponding one of the plurality of switches and coupled to the buffer and the charge pump circuit to respectively receive the buffer signal and the boost voltage, and converts a voltage level of a corresponding one of the control signals according to the buffer signal and the boost voltage to generate and output a corresponding one of the plurality of switching signals to the corresponding one of the plurality of switches.

7. The automatic gain controller according to claim 6, wherein each of the voltage level shifting circuits comprises:
an inverter, having an input terminal for receiving the corresponding one of the plurality of control signals, and an output terminal outputting an inverted signal;
a first transistor, having a first terminal coupled to the charge pump circuit to receive the boost voltage, a second terminal, and a control terminal;
a second transistor, having a first terminal, a second terminal and a control terminal respectively coupled to the first terminal, the control terminal and the second terminal of the first transistor;
a third transistor, having a first terminal coupled to the second terminal of the first transistor, a second terminal, and a control terminal coupled to the buffer to receive the buffer signal;
a fourth transistor, having a first terminal coupled to the second terminal of the second transistor, a second terminal providing the corresponding one of the plurality of switching signals, and a control terminal coupled to the buffer to receive the buffer signal;
a fifth transistor, having a first terminal coupled to the second terminal of the third transistor, a second terminal, and a control terminal for providing a supply voltage;
a sixth transistor, having a first terminal coupled to the second terminal of the fourth transistor, a second terminal, and a control terminal for receiving the supply voltage;
a seventh capacitor, having a first terminal coupled to the second terminal of the fifth transistor, a second terminal, and a control terminal coupled to the output terminal of the inverter to receive the inverted signal; and
an eighth transistor, having a first terminal coupled to the second terminal of the sixth transistor, a second terminal coupled to the second terminal of the seventh transistor, and a control terminal coupled to the input terminal of the inverter.

8. The automatic gain controller according to claim 7, wherein each of the first transistor to the fourth transistor is a P-type MOSFET, and each of the fifth transistor to the eighth transistor is an N-type MOSFET.

9. The automatic gain controller according to claim 7, wherein each of the first transistor to the eighth transistor is a low dropout transistor.

10. The automatic gain controller according to claim 1, wherein the audio amplifier is a class D amplifier.
